(19) United States
(12) Patent Application Publication
(10) Pub. No.: US 2007/0281393 A1
(43) Pub. Date: Dec. 6, 2007

(54) METHOD OF FORMING A TRACE EMBEDDED PACKAGE

(76) Inventors: Viswanadam Gautham, Singapore (SG); Lan Chu Tan, Jalan Pelangi (MY); Heng Keong Yip, Selangor Darul Ehsan (MY)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/421,006

(22) Filed: May 30, 2006

(51) Int. Cl. H01L 21/60

(52) U.S. Cl. 438/113; 438/123; 438/124

(57) ABSTRACT

A method of forming a semiconductor package (32) includes etching a conductive sheet (10) to form a first interconnection system (12). An integrated circuit (IC) die (22) is placed on and electrically connected to the first interconnection system (12). Next, a molding operation is performed to encapsulate the IC die (22), the electrical connections (24, 26) and at least a portion of the first interconnection system (12). A portion (20) of the conductive sheet (10) is then removed to expose a surface (30) of the first interconnection system (12). A second interconnection system (34) then is formed over the exposed surface (30) of the first interconnection system (12).

### BACKGROUND OF THE INVENTION

The present invention relates to the packaging of semiconductor devices in general and more specifically to a method of forming a trace embedded semiconductor package.

Conventional semiconductor packages typically include an integrated circuit (IC) die attached and electrically connected to a plastic or ceramic substrate. A drawback associated with current substrate technology is the cost of the ceramic and plastic substrates; ceramic and plastic substrates are expensive. Further, although adequate for current applications, current substrate technology will soon be unable to keep up with the demand for thinner profile semiconductor packages and the need to dissipate the additional heat generated by the more powerful semiconductor chips that are being introduced, while maintaining a competitive price. In view of the foregoing, there exists a need for an inexpensive method of manufacturing a thin profile semiconductor package with good heat dissipation properties.

Accordingly, it is an object of the present invention to provide an inexpensive method of forming a thin profile semiconductor package with improved heat dissipation characteristics.

### BRIEF DESCRIPTION OF THE DRAWINGS

The following detailed description of preferred embodiments of the invention will be better understood when read in conjunction with the appended drawings. The present invention is illustrated by way of example and is not limited by the accompanying figures, in which like references indicate similar elements. It is to be understood that the drawings are not to scale and have been simplified for ease of understanding the invention.

FIG. 1 is an enlarged, top plan view of a conductive sheet having a first interconnection system formed thereon in accordance with an embodiment of the present invention;

FIG. 2 is a cross-sectional view of the conductive sheet of FIG. 1;

FIG. 3 is a cross-sectional view of a plurality of integrated circuit (IC) dies placed on and electrically connected to the first interconnection system of FIG. 1 via a plurality of bumps;

FIG. 4 is a cross-sectional view of a plurality of IC dies placed on and electrically connected to the first interconnection system of FIG. 1 via a plurality of wire bonded wires;

FIG. 5 is a cross-sectional view of the IC dies of FIG. 3 encapsulated by a mold compound;

FIG. 6 is a cross-sectional view of the encapsulated IC dies of FIG. 5 with a portion of the conductive sheet removed to expose a surface of the first interconnection system;

FIG. 7 is a top plan view of the exposed surface of the encapsulated first interconnection system of FIG. 6;

FIG. 8 is an enlarged cross-sectional view of a plurality of semiconductor packages in accordance with an embodiment of the present invention;

FIG. 9 is a cross-sectional view of the semiconductor packages of FIG. 8 having a plurality of solder balls attached thereto; and

FIG. 10 is a bottom plan view of one of the semiconductor packages of FIG. 9.

### DETAILED DESCRIPTION OF THE PREFERRED EMBODIMENTS

The detailed description set forth below in connection with the appended drawings is intended as a description of the presently preferred embodiments of the invention, and is not intended to represent the only form in which the present invention may be practiced. It is to be understood that the same or equivalent functions may be accomplished by different embodiments that are intended to be encompassed within the spirit and scope of the invention.

To achieve the objects and advantages discussed above and others, the present invention provides a method of forming a semiconductor package including the step of etching a conductive sheet to form a first interconnection system. An integrated circuit (IC) die is placed on and electrically connected to the first interconnection system. Next, a molding operation is performed to encapsulate the IC die, the electrical connections and at least a portion of the first interconnection system. A portion of the conductive sheet is then removed to expose a surface of the first interconnection system. A second interconnection system then is formed over the exposed surface of the first interconnection system.

The present invention also provides a method of forming a plurality of semiconductor packages including the step of etching a conductive sheet to form a first interconnection system. A plurality of IC dies is placed on and electrically connected to the first interconnection system. Next, a molding operation is performed to encapsulate the IC dies, the electrical connections and at least a portion of the first interconnection system. A portion of the conductive sheet is then removed to expose a surface of the first interconnection system. Thereafter, a second interconnection system is formed over the exposed surface of the first interconnection system. Finally, a singulating operation is performed to separate adjacent ones of the IC dies, thereby forming a plurality of semiconductor packages. A plurality of solder balls may be attached to the second interconnection system of the singulated semiconductor packages.

The present invention further provides a method of forming a plurality of semiconductor packages including the step of patterning a conductive sheet with a trace mask to form traces and first interconnect pads. The interconnect pads are plated with one of a conductive metal and a conductive alloy and respective ones of the interconnect pads are electrically coupled to a plurality of IC dies. Next, the IC dies and the interconnect pads are encapsulated with a mold compound. The conductive sheet is then etched to expose the traces. A passivation material is deposited on the exposed traces and patterned to form an interconnection system. A conductive material is deposited over the patterned passivation material and a solder mask is deposited over the conductive material on the patterned passivation material to form second interconnect pads. A singulating operation then is performed to separate adjacent ones of the IC dies, thereby forming a plurality of semiconductor packages.

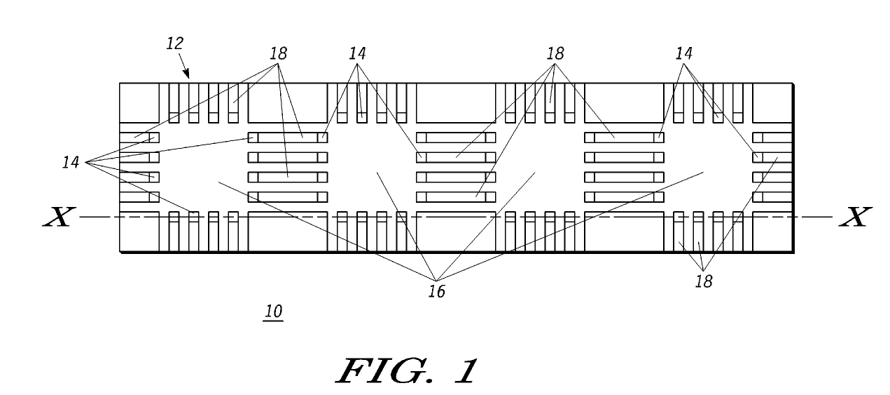

Referring now to FIG. 1, a top plan view of a conductive sheet 10 such as, for example, a copper foil, having a first interconnection system 12 formed thereon is shown. The first interconnection system 12 includes a plurality of first interconnect pads or bonding pads 14 formed around respective ones of a plurality of die support areas 16, and a plurality of traces 18 extending from the respective first interconnect pads 14.

Although four (4) die support areas 16 are shown in FIG. 1, those of skill in the art will understand that the present invention is not limited by the number of die support areas on the conductive sheet 10; there can be fewer or more die support areas 16 on the conductive sheet 10. Further, although the first interconnect system 12 and die support areas 16 are shown in strip format, the invention is equally applicable to an array format. Additionally, it should be understood that the present invention also is not limited by the layout of the first interconnect pads 14, or by that of the traces 18. Those of skill in the art will understand that the layout of the traces 18 depends on the functionality of the traces 18, that is whether a particular trace 18 is a signal trace, a ground trace or a power supply trace, and on the application of the resultant semiconductor package, and that the dimensions of different traces 18 may vary. For example, power and ground traces may be wider than signal traces.

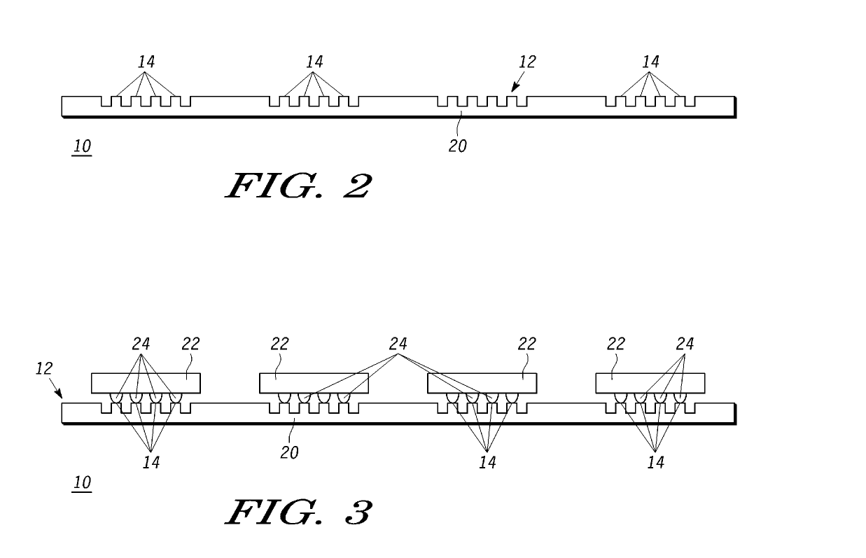

Referring now to FIG. 2, a cross-sectional view of the conductive sheet 10 along a line X-X in FIG. 1 is shown. The first interconnection system 12 is formed on the conductive sheet 10 by patterning the conductive sheet 10 with a trace mask and etching the conductive sheet 10 using a known etching technique such as, for example, wet etching or dry etching. As is known by those of skill in the art, such etching includes the steps of coating the copper foil or conductive sheet 10 with a resist or dry film lamination, exposing and developing the resist or dry film, and etching. A portion 20 of the conductive sheet 10 is maintained as a base for the first interconnection system 12, providing support for subsequent processing steps. Once etching is completed, the trace mask is removed from the conductive sheet 10. That is, the resist or dry film is stripped from the etched conductive sheet 10. The first interconnect pads 14 may be selectively plated with a conductive metal such as, for example, tin or gold, or a conductive alloy.

Referring now to FIG. 3, a plurality of integrated circuit (IC) dies 22 having a plurality of bumps 24 on one side thereof are placed on the first interconnection system 12 as shown. More particularly, the bumps 24 on the IC dies 22 are placed against the corresponding first interconnect pads 14 on the first interconnection system 12. The bumps 24 are subjected to heat and/or vibration, as is known in the art, to electrically couple the bumps 24 to the corresponding first interconnect pads 14, thereby electrically connecting the IC dies 22 and the first interconnection system 12. The IC dies 22 may be processors, such as digital signal processors (DSPs), special function circuits, such as memory address generators, or circuits that perform any other type of function. The IC dies 22 are not limited to a particular technology such as CMOS, or derived from any particular wafer technology. Further, the present invention can accommodate various die sizes, as will be understood by those of skill in the art. A typical example is a memory die having a size of about 15 mm by 15 mm. As will be understood by those of skill in the art, the present invention is not limited by the type of first-level interconnections (i.e., the bumps 24 to the first interconnect pads 14) formed between the IC dies 22 and the first interconnection system 12. For example, in another embodiment, the first interconnection system 12 may be directly connected to the under-bump metallization (UBM) on the IC dies 22, thereby reducing the package profile of the resulting semiconductor packages since the IC dies 22 do not therefore require bumping. In yet another embodiment, the first interconnection system 12 may be electrically connected to the IC dies 22 via a plurality of wires as described below.

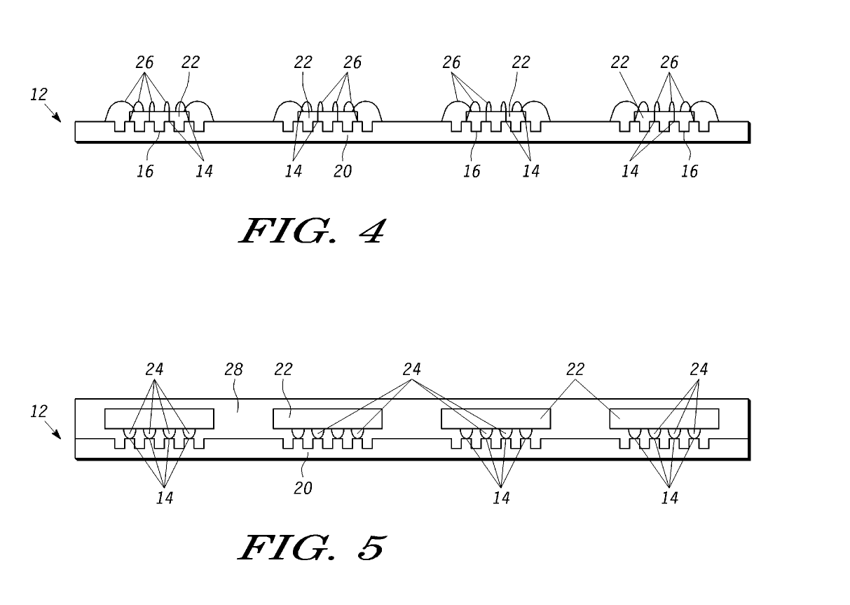

Referring now to FIG. 4, the IC dies 22 are placed on the first interconnection system 12 at the die support areas 16 (FIG. 1) and electrically connected to the respective first interconnect pads 14 with a plurality of wires 26. The IC dies 22 may be attached to the die support areas 16 using a die attach adhesive or double-sided tape, as are known in the art. The wires 26 electrically connect bonding pads on the IC dies 22 to respective first interconnect pads 14 on the first interconnection system 12. A known wirebonding process is used to make the electrical connections. The wires 26 may be made of gold (Au) or other electrically conductive materials as are known in the art and commercially available.

As can be seen from FIGS. 3 and 4, the first interconnection system 12 provides a medium for die interconnection, thereby reducing packaging costs by doing away with the need for ceramic or plastic substrates. Additionally, the present invention also achieves a thinner profile package by eliminating the use of plastic or ceramic substrates. Advantageously, the traces 18 (FIG. 1) of the first interconnection system 12 serve as a heat spreader to dissipate heat generated by the IC dies 22 coupled to the first interconnection system 12. The present invention can be used to package IC dies for high powered applications by increasing the thickness of the traces 18. In one embodiment, the traces 18 have a thickness of at least about 75 microns (μm).

Referring now to FIG. 5, the IC dies 22, together with the bumps 24 and the first interconnect pads 14 on the first interconnection system 12, are encapsulated with a mold compound 28. A molding operation such as, for example, an injection molding process may be used to perform the encapsulation. The mold compound 28 may comprise well known commercially available molding materials such as plastic or epoxy. The IC dies 22 are preferably fully encapsulated for protection from adverse environments and contaminants. The first interconnect system 12 and encapsulated IC dies 22 may be in the form of a molded array. Because the first interconnection system 12 acts as a heat spreader, there is no need for an additional step of attaching a separate heat spreader to the IC dies 22 either before or after encapsulation. Consequently, the number of process steps involved in the packaging process of the present invention is reduced.

Referring now to FIG. 6, the portion 20 of the conductive sheet 10 is removed to expose a surface 30 of the first interconnection system 12. The portion 20 of the conductive sheet 10 may be removed by wet etching, dry etching, grinding, Chemical Mechanical Polishing (CMP) or other removal techniques as are known in the art. To facilitate processing, the molded array is flipped or turned over.

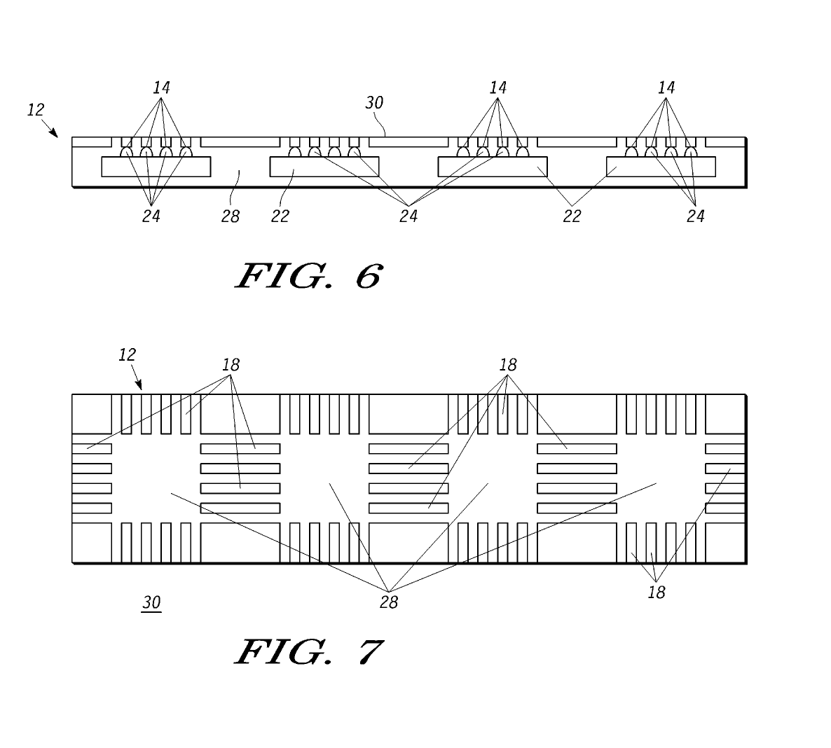

Referring now to FIG. 7, a top plan view of the exposed surface 30 of the encapsulated first interconnection system 12 is shown. As can be seen from FIG. 7, the traces 18 on the first interconnection system 12 are exposed when the portion 20 of the conductive sheet 10 is removed.

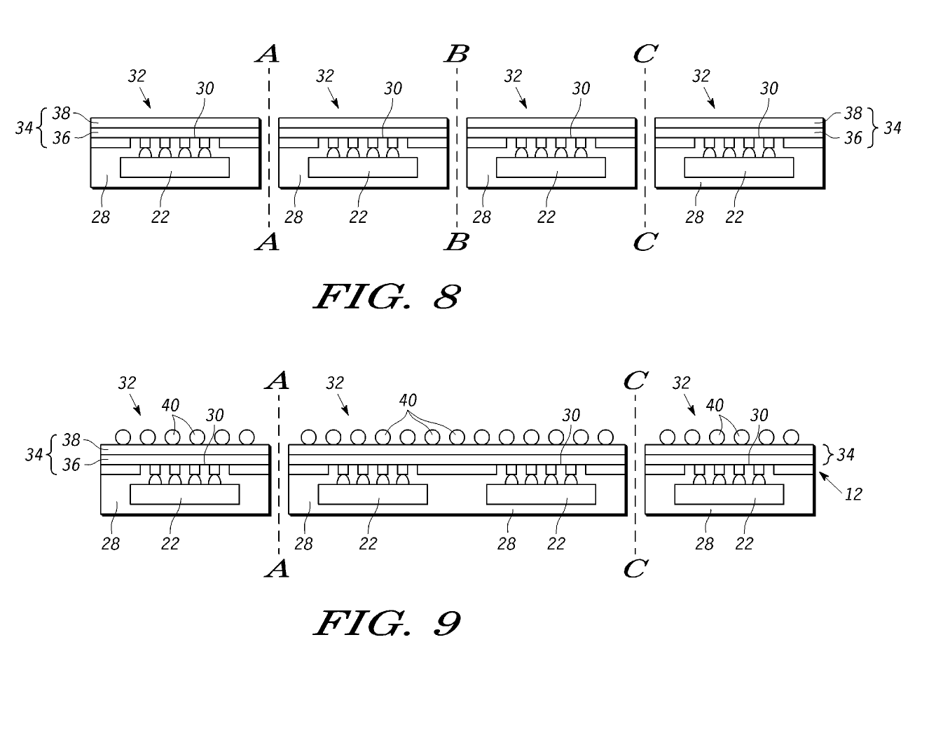

Referring now to FIG. 8, a cross-sectional view of a plurality of semiconductor packages 32 is shown. As can be seen from FIG. 8, a second interconnection system 34 is formed over the exposed surface 30 of the first interconnection system 12. The second interconnection system 34 includes a redistribution layer 36 to reroute the first interconnection system 12 to an area array of interconnection points. The area array of interconnection points preferably is plated with nickel, gold or an alloy thereof. The second interconnection system 34 is formed by depositing a layer of passivation material on the exposed traces of the first interconnection system 12. The layer of passivation material is patterned to expose a plurality of interconnect pads. Next, a layer of conductive material, such as copper plating, is deposited over the patterned passivation material. The copper plating will form the redistribution layer 36. Finally, a solder mask 38 is deposited over the redistribution layer 36 on the patterned passivation material to form a plurality of second interconnect pads. Adjacent ones of the IC dies 22 are separated along the vertical lines A-A, B-B and C-C via a singulating operation such as, for example, saw singulation to form individual semiconductor packages 32. In this particular example, the singulating step is performed after the formation of the second interconnection system 34. However, those of skill in the art will understand that the singulating step also can be performed after the step of attaching a plurality of solder balls to the second interconnection system 34 of the semiconductor packages 32, described below with reference to FIG. 9.

Referring now to FIG. 9, a cross-sectional view of the semiconductor packages 32 having a plurality of conductive balls 40 attached thereto is shown. Note that in FIG. 9, the center package includes two IC dies 22, illustrating that the singulation could be performed, for instance, only along lines A-A and C-C such that a multi-die package may be formed. The conductive balls 40 are attached to the second interconnection system 34 of the singulated semiconductor packages 32. The conductive balls 40 may be attached using a solder paste screen printing method or by other attachment methods known in the art.

Although FIGS. 3-6, 8 and 9 show only four (4) dies 22 being attached, it will be understood that more or fewer dies 22 may be attached to the first interconnection system 12, depending on the size of the first interconnection system 12, the size of the IC dies 22, and the required functionality of the resulting semiconductor packages 32.

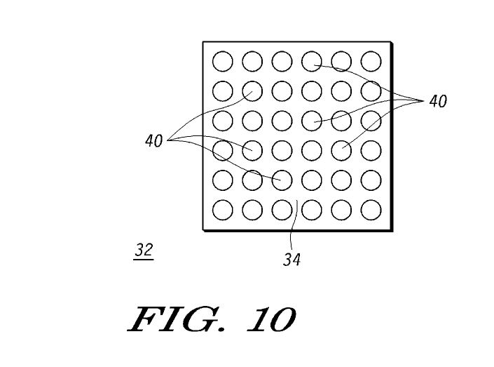

Referring now to FIG. 10, a bottom plan view of one of the semiconductor packages 32 of FIG. 9 is shown. As can be seen from FIG. 10, the conductive balls 40 are attached to respective interconnection points in the area array on the second interconnection system 34.

While a method of forming a packaged semiconductor device has been described, it should be understood that the packaged device formed by the afore-described method also is part of the invention. That is, the present invention further is a semiconductor package, including a first interconnection system formed from a conductive sheet; an IC die attached and electrically connected to the first interconnection system; a mold compound encapsulating the IC die, the electrical connections and at least a portion of the first interconnection system; and a second interconnection system formed over the first interconnection system, wherein the second interconnection system reroutes the first interconnection system into an area array of interconnection points.

The semiconductor package may have a plurality of solder balls attached to respective ones of the interconnection points in the area array. The first interconnection system includes a plurality of traces, and the traces have a thickness of at least about 75 μm. The first interconnection system also includes a plurality of bonding pads.

As is evident from the foregoing discussion, the present invention provides an inexpensive method of forming a thin profile semiconductor package by eliminating the use of plastic or organic substrates from the packaging process. Moreover, because the embedded traces serve as a heat spreader, the resultant semiconductor packages have improved heat dissipation characteristics and can therefore be used in high powered applications. Additionally, the resultant semiconductor packages afford greater reliability than conventional packages formed with organic substrates, which are often susceptible to failure due to the substantial differences in coefficients of thermal expansion (CTE) between the silicon IC die and the organic substrate. Furthermore, multiple substrates in array (MAP) format can be processed simultaneously with the present invention, thereby achieving high throughput. The present invention is also able to withstand high temperature solder reflows that are required for high lead and lead free solders.

While the preferred embodiments of the invention have been illustrated and described, it will be clear that the invention is not limited to these embodiments only. For instance, apart from the Ball Grid Array (BGA) packages described, the present invention may also be applied in the manufacture of other types of semiconductor packages such as, for example, Land Grid Array (LGA) and System in Package (SIP) packages. Numerous modifications, changes, variations, substitutions and equivalents will be apparent to those skilled in the art without departing from the spirit and scope of the invention as described in the claims.

1. A method of forming a semiconductor package, comprising:
etching a conductive sheet to form a first interconnection system;
placing an IC die on the first interconnection system;
electrically connecting the IC die and the first interconnection system;
performing a molding operation to encapsulate the IC die, the electrical connections and at least a portion of the first interconnection system;
removing a portion of the conductive sheet to expose a surface of the first interconnection system; and
forming a second interconnection system over the exposed surface of the first interconnection system.

2. The method of forming a semiconductor package of claim 1, wherein the conductive sheet comprises a copper foil.

3. The method of forming a semiconductor package of claim 2, wherein the conductive sheet is removed by one of wet etching, dry etching, grinding and Chemical Mechanical Polishing (CMP).

4. The method of forming a semiconductor package of claim 1, further comprising depositing a layer of passivation on the exposed surface of the first interconnection system.

5. The method of forming a semiconductor package of claim 4, further comprising patterning the layer of passivation to expose a plurality of interconnect pads.

6. The method of forming a semiconductor package of claim 5, further comprising the step of depositing a layer of conductive material over the layer of passivation.

7. The method of forming a semiconductor package of claim 1, wherein the second interconnection system includes a redistribution layer to reroute the first interconnection system to an area array of interconnection points.

8. The method of forming a semiconductor package of claim 7, further comprising plating the area array of interconnection points with one of nickel, gold and an alloy thereof.

9. The method of forming a semiconductor package of claim 8, further comprising attaching a plurality of solder balls to respective ones of the interconnection points in the area array.

10. The method of forming a semiconductor package of claim 9, wherein the plurality of solder balls is attached using a solder paste screen printing method.

11. The method of forming a semiconductor package of claim 1, wherein the first interconnection system includes a plurality of traces.

12. The method of forming a semiconductor package of claim 11, wherein the plurality of traces has a thickness of at least about 75 microns (μm).

13. The method of forming a semiconductor package of claim 1, wherein the first interconnection system includes a plurality of bonding pads.

14. The method of forming a semiconductor package of claim 13, further comprising selectively plating the plurality of bonding pads.

15. The method of forming a semiconductor package of claim 14, wherein the plurality of bonding pads is selectively plated with one of tin and gold.

16. The method of forming a semiconductor package of claim 1, wherein the IC die is fully encapsulated.

17. A method of forming a plurality of semiconductor packages, the method comprising:
etching a conductive sheet to form a first interconnection system;
placing a plurality of IC dies on the first interconnection system;
electrically connecting the IC dies and the first interconnection system;
performing a molding operation to encapsulate the IC dies, the electrical connections and at least a portion of the first interconnection system;
removing a portion of the conductive sheet to expose a surface of the first interconnection system;
forming a second interconnection system over the exposed surface of the first interconnection system; and
performing a singulating operation to separate adjacent ones of the IC dies, thereby forming a plurality of semiconductor packages.

18. The method of forming a plurality of semiconductor packages of claim 17, further comprising the step of attaching a plurality of solder balls to the second interconnection system of the singulated semiconductor packages.

19. A method of forming a plurality of semiconductor packages, the method comprising:
patterning a conductive sheet with a trace mask to form traces and first interconnect pads;
plating the interconnect pads with one of a conductive metal and a conductive alloy;
electrically coupling a plurality of IC dies to respective ones of the interconnect pads;
encapsulating the IC dies and the interconnect pads with a mold compound;
etching the conductive sheet to expose the traces;
depositing a passivation material on the exposed traces;
patterning the passivation material to form an interconnection system;
depositing a conductive material over the patterned passivation material;
depositing a solder mask over the conductive material on the patterned passivation material to form second interconnect pads; and
performing a singulating operation to separate adjacent ones of the IC dies, thereby forming a plurality of semiconductor packages.

20. The method of forming a plurality of semiconductor packages of claim 19, further comprising the step of attaching a plurality of solder balls to the second interconnect pads on the singulated IC dies.
